(19) United States
(12) Patent Application Publication
(10) Pub. No.: US 2004/0233878 A1
(43) Pub. Date: Nov. 25, 2004

(54) Wireless network receiver and a method for the wireless network receiver to check the integrity of a received MSDU

(76) Inventors: Fang Cheng Liu, Hsinchu (TW); Syu Ding-Jyan, Hsinchu (TW)

Correspondence Address: Harold V. Stotland, Seyfarth Shaw, 42nd Floor, 55 East Monroe Street, Chicago, IL, 60603-5803, US

(21) Appl. No.: 10/687,359

(22) Filed: Oct. 16, 2003

(30) Foreign Application Priority Data
May 23, 2003 (TW) 092113988

(51) Int. Cl. H04Q 7/24; H03M 13/00; H04L 12/26; H04J 3/14

(52) U.S. Cl. 370/338; 714/776; 370/252; 714/758

(57) ABSTRACT

The transmitter of the present invention calculates a first integrity check value of the MSDU and fragments it into several MPDUs before transmitting it to the receiver in sequence. The receiver firstly calculate a second integrity check value from these MPDUs in sequence by a computing unit, and verifies the integrity of the received MSDU by checking if the first integrity check value is equal to the second integrity check value. If the first integrity check value is equal to the second integrity check value, a CPU shall reassemble these MPDU into the MSDU.

### BACKGROUND OF THE INVENTION

(A) Field of the Invention

The present invention relates to a wireless network receiver and a method for the wireless network receiver to check the integrity of a received MSDU, and more particularly, to a wireless network receiver and a method for a wireless network receiver to check the integrity of a received MSDU at first and then decide whether to reassemble the MSDU.

(B) Description of the Related Art

Wireless network transmission technology uses radio wave as the data transmission medium. However, radio wave tends to be interfered and is not appropriate for redundant data transmission; therefore, an original data to be transmitted via wireless network shall be divided into data fragments by a transmitter before being transmitted to a receiver in sequence in practice. After collecting all the data fragments of the original data, the receiver reassembles the data fragments into the original data. According to IEEE 802.11 wireless communication protocol, the data before fragmentation is called MSDU (Media access control Service Data Unit), while the fragmented data with header added is called MPDU (Media access control Protocol Data Unit). In addition, an MSDU can become an MPDU by directly adding header without fragmentation, while the MPDU mentioned in this patent application refers to those that come from fragments of an MSDU.

FIG. 1 is a schematic diagram showing the transmission process of an MSDU 12 from a transmitter 10 to a receiver 20 according to the prior art. As shown in FIG. 1, the transmitter 10 first performs a message integrity check (MIC) calculation process to obtain a first integrity check value 14 of an MSDU 12, which is appended to the MSDU 12. Then, the transmitter 10 performs a fragmentation process to fragment the MSDU 12 into three smaller MPDU 16, and the first integrity check value 14 is appended to the last MPDU 16. Lastly, the transmitter 10 transmits the MPDU 16 in sequence to the receiver 20 via the wireless network.

FIG. 2 is a schematic diagram showing the operation of the receiver 20 after receiving the MSDU 12. As shown in FIG. 2, after receiving the MPDU 16 in sequence, the receiver 20 performs a data reassembling process to reassemble MPDU 16 into the original MSDU 12 and the first integrity check value 14. Then, the receiver 20 must perform a calculation process to calculate a second integrity check value 22 from the reassembled MSDU 12. An integrity check process is then performed to check if the received MSDU 12 is correct by checking whether the second integrity check value 22 is equal to the first integrity check value 14 calculated by the transmitter 10.

The receiver 20 reassembles the MSDU 12 and calculates the second integrity check value 22 with an embedded CPU. Since the second integrity check value 22 can be calculated only after the MSDU 12 is reassembled, there is no way for the embedded CPU to verify the integrity of the received MSDU 12 before the reassembling process is completed. Besides, since the embedded CPU must reassemble each MSDU 12 according to the prior art, it also wastes time to receive and reassemble the data that is verified to be lacking of integrity by subsequent integrity check process. Therefore, the overall performance of prior art technologies is subject to improvement.

### SUMMARY OF THE INVENTION

The objective of the present invention is to provide a wireless network receiver and a method for the wireless network receiver to check the integrity of a received MSDU at first and then decide whether to reassembles the MSDU.

To achieve the above-mentioned objective and to avoid the problems of the prior art, the present invention discloses a wireless network receiver and a method for the wireless network receiver to check the integrity of a received MSDU first and then decide whether to reassembles the MSDU. A transmitter calculates a first integrity check value of the MSDU, fragments the MSDU into a plurality of MPDUs, and then sends these MPDUs to a receiver in sequence. The wireless network receiver comprises a receiving queue, a computing unit and a first memory. According to the present invention, the computing unit calculates a second integrity check value from these MPDUs in sequence, and then checks the integrity of the received MSDU by checking whether or not the second integrity check value is equal to the first integrity check value. If the second integrity check value is equal to the first integrity check value, the wireless network receiver has received an integrated MSDU. The MPDUs received by the wireless network receiver are stored in a second memory. If the second integrity check value is equal to the first integrity check value, a CPU reads all MPDU of the same MSDU from the second memory and reassembles them into the MSDU.

Compared with the prior art technology, the present invention can decrease the load of the CPU since the computing unit checks the integrity of the MSDU received by the wireless network receiver. In addition, the CPU only reassembles the MPDUs that have passed through integrity check into the MSDU, thus no time is wasted to reassemble incomplete data and the overall performance of the receiver is enhanced.

### BRIEF DESCRIPTION OF THE DRAWINGS

Other objectives and advantages of the present invention will become apparent upon reading the following description and upon reference to the accompanying drawings in which:

FIG. 1 is a schematic diagram showing the transmission of an MSDU from a transmitter to a receiver according to the prior art;

FIG. 2 is a schematic diagram showing the operation of the receiver after receiving an MSDU;

FIG. 3 is a schematic diagram showing the transmission of an MSDU from a transmitter to a receiver according to the present invention;

FIG. 4 illustrates some important fields of an MPDU;

FIG. 5 is a functional block diagram of a receiver according to the present invention;

FIG. 6 illustrates some important fields of a data stored in a first memory according to the present invention;

FIG. 7a is schematic diagram of a second memory according to the present invention;

FIG. 7b is a schematic diagram showing the correspondence between a descriptor and an MPDU according to the present invention;

FIG. 8 is a flow chart showing the operation of a computing unit according to the present invention; and

FIG. 9 is a flow chart showing the calculation process of the integrity check value according to the present invention.

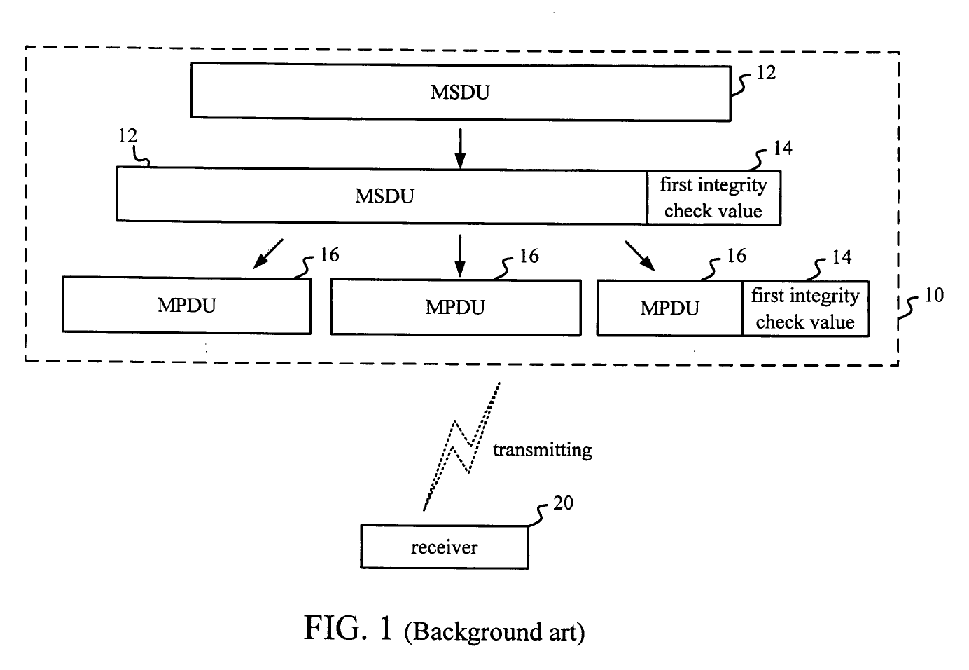

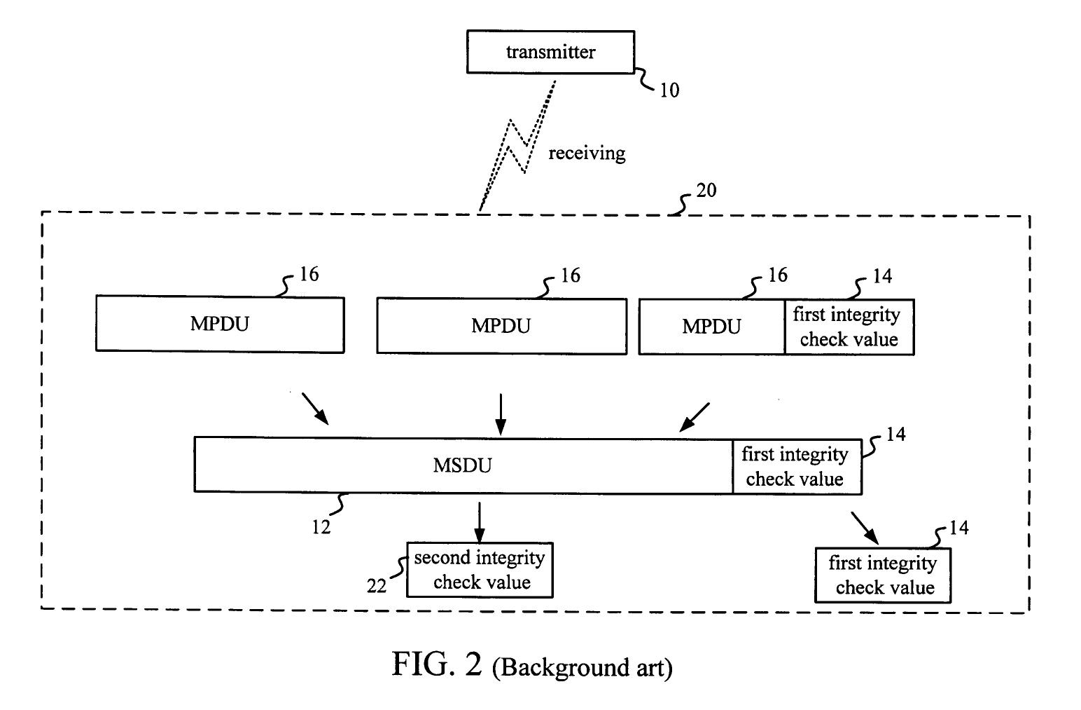

### DETAILED DESCRIPTION OF THE INVENTION

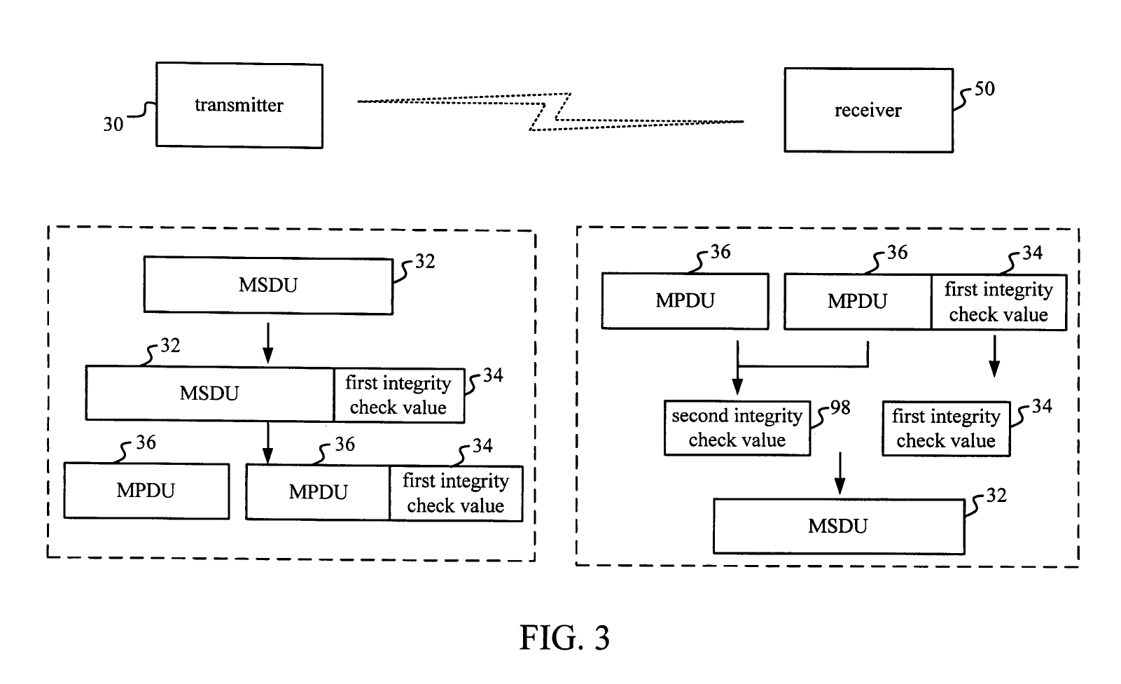

FIG. 3 is a schematic diagram showing the transmission of an MSDU 32 from a wireless network transmitter 30 to a wireless network receiver 50 according to the present invention. In accordance with IEEE 802.11 wireless communication protocol, the wireless network transmitter 30 calculates a first integrity check value 34 from the MSDU 32, and appends the first integrity check value 34 to the MSDU 32. The wireless network transmitter 30 then performs a fragmentation process to fragment the MSDU 32 into two MPDUs 36, wherein the first integrity check value 34 is appended to the last MPDU 36 of the MSDU 32. Finally, the wireless network transmitter 30 sends these MPDUs 36 to the wireless network receiver 50 in sequence. After receiving the MPDU 36, the wireless network receiver 50 calculates a second integrity check value 98 from the received MPDU 36, and checks the integrity of the MSDU 32 by checking whether or not the second integrity check value 98 is equal to the first integrity check value 34.

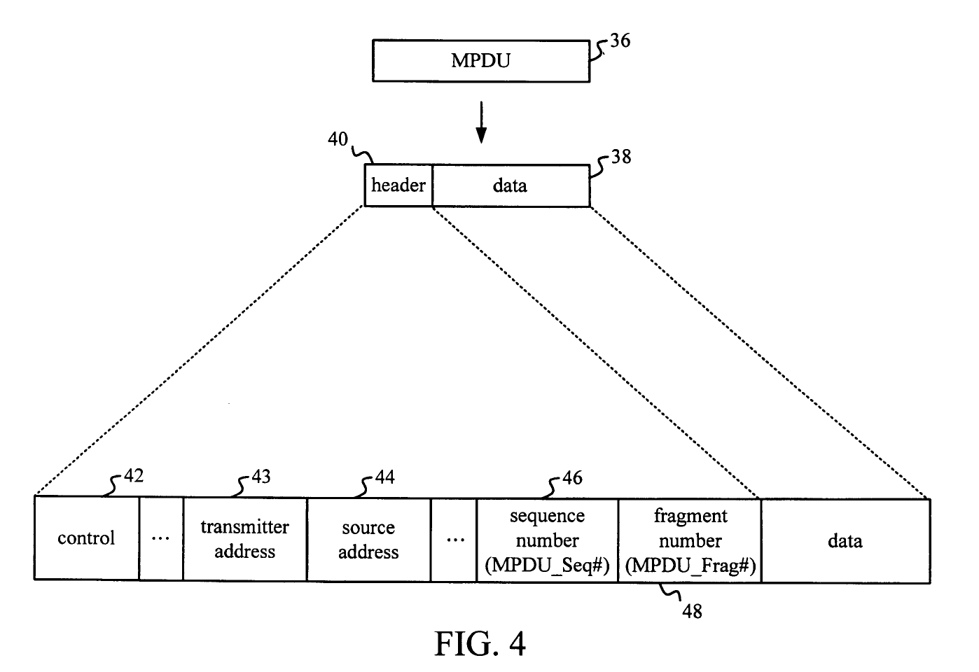

FIG. 4 illustrates some important fields of the MPDU 36. As shown in FIG. 4, the MPDU 36 comprises a header 40 and a data 38, and the header 40 includes a control field 42, a transmitter address field 43, a destination address field 44, a sequence number field (MPDU_Seq#_) 46 and a fragment number field (MPDU Frag#) 48. The sequence number field 46 is used to record the sequence number of the MPDU 36, wherein the value of the sequence number in a range from 0 to 4095 and repeated after reaching the limit. The MPDU 36 fragmented from the same MSDU 32 and all fragments use the same sequence number. The fragment number identifies the fragment sequence of the MPDU 36 in the MSDU 32. The value of the first fragment (or MSDU that is not fragmented) is 0, and 1 is added to the following fragments in sequence until reaching 15, which are then repeated in turn.

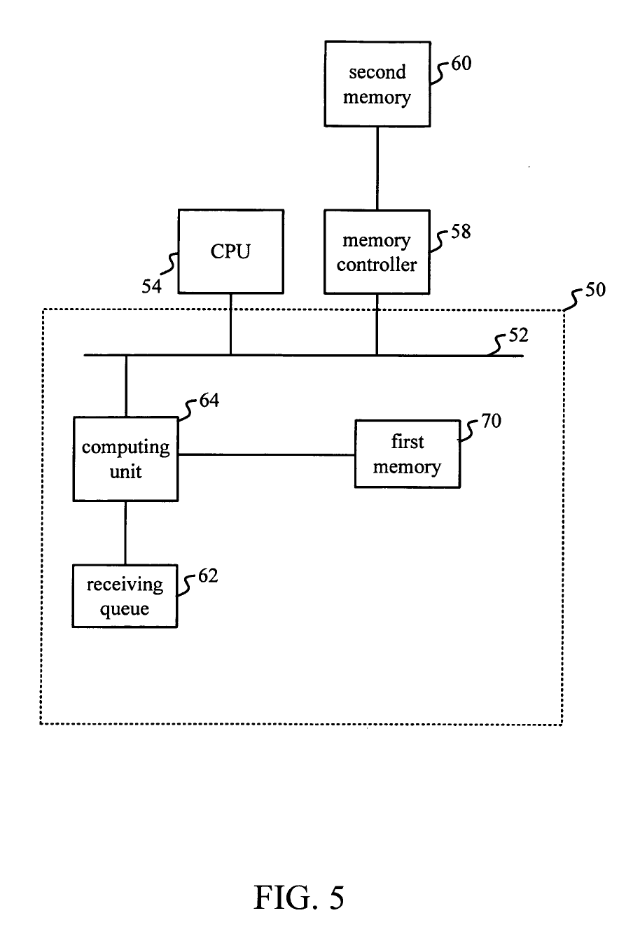

FIG. 5 is a functional block diagram of the wireless network receiver 50 according to the present invention. As shown in FIG. 5, the wireless network receiver 50 comprises a system bus 52, a CPU 54 electrically connected to the system bus 52, a memory controller 58 electrically connected to the system bus 52, a receiving queue 62 for receiving the MPDU, a computing unit 64 electrically connecting the receiving queue 62 and the system bus 52, and a first memory 70 electrically connected to the computing unit 64. The computing unit 64 is used to calculate the integrity check value of the MSDU 32, while the first memory 70 is used to store relevant information required by the computing unit 64.

The memory controller 58 is used to control the data access of a second memory 60, while the second memory 60 is used to store the MPDU 36. The CPU 54 can access the MPDUs 36 stored in the second memory 60 through the memory controller 58, and reassemble them into the MSDU 32. Although the CPU 54 and the memory controller 58 shown in FIG. 5 are positioned outside of the wireless network receiver 50, one skilled in the art should realize that the wireless network receiver could be designed to comprise an embedded CPU for reassembling the MPDUs 36 into the MSDU 32 and memory controller for controlling the data access to the second memory 60.

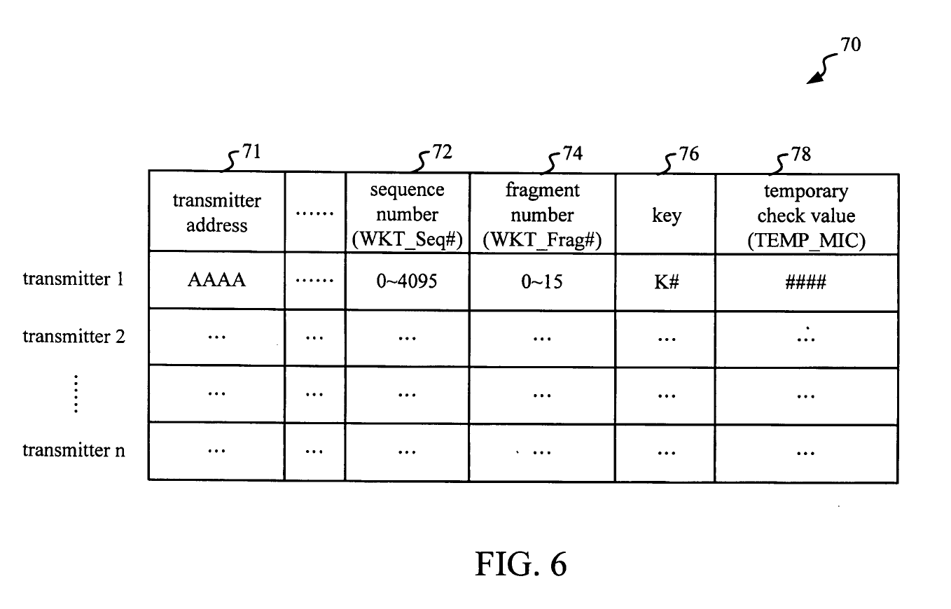

FIG. 6 illustrates some important fields of a piece of data stored in the first memory 70 according to the present invention, wherein the first memory 70 can be a static RAM. As shown in FIG. 6, the data stored in the first memory 70 comprises transmitter address field 71, sequence number field (WKT_seq#) 72, fragment number field (WKT_Frag#) 74, key field 76 and a temporary check value field (TEMP_MIC) 78. The key field 76 stores keys for the computing unit 64 to calculate integrity check value, while the temporary check value field 78 stores temporary check values calculated by the computing unit 64 upon completing the calculation of each MPDU 36.

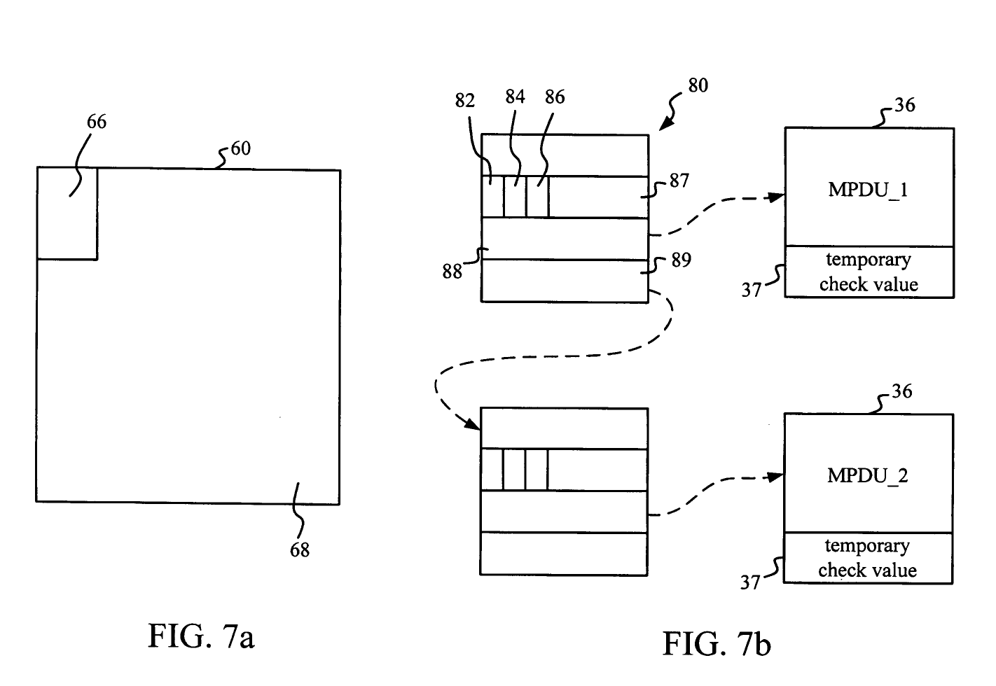

FIG. 7a is a schematic diagram of the second memory 60 according to the present invention, wherein the second memory 60 may be a dynamic RAM. As shown in FIG. 7a, the second memory 60 comprises a descriptor storage region 66 and a data storage region 68. The MPDU 36 received by the wireless network receiver 50 is stored in the data storage area 68, and each of them is provided with a descriptor 80.

FIG. 7b is a schematic diagram showing the correspondence between the descriptor 80 and the MPDU 36. As shown in FIG. 7b, the first field 82 (last MPDU, LM) of the descriptor 80 is used to record information indicating whether the MPDU 36 is the last one of the MSDU 32. The second field 84 (Verification OK, VOK) is used to record the integrity check status of the MSDU 32. The third field 86 (Corrupted, C) is used to record information indicating whether there is any error occurred on receiving the MSDU 32. The fourth field 87 is used to record the length of the MPDU 36 corresponding to the descriptor 80. The fifth field 88 is a pointer pointing to the storage address of the MPDU 36 corresponding to the descriptor 80. The sixth field 89 is used to record the storage address of the next descriptor 80, which corresponds to the next MPDU 36 of the MSDU 32.

Each MPDU 36 stored in the data storage area 68 is appended with a temporary check value field 37, which is used to record the temporary check value calculated by the computing unit 64 from the MPDU 36. If the MPDU 36 is the last one of the MSDU 32 or the MSDU is transmitted without fragmentation, the storage value of the temporary check value field 37 is the integrity check value of MSDU 32, i.e., the second integrity check value 98.

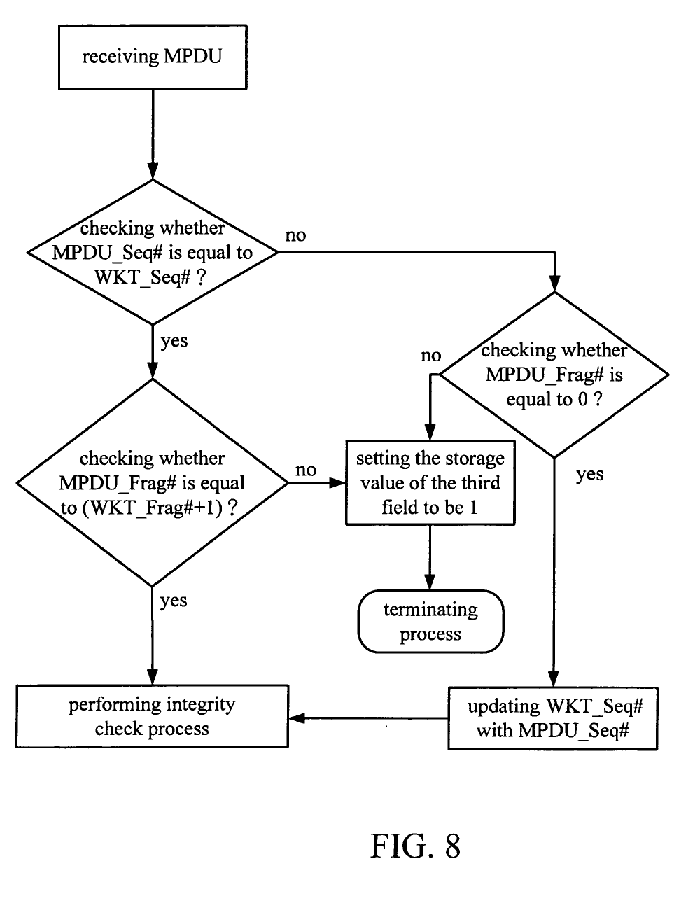

FIG. 8 is a flow chart showing the operation of a computing unit 64 according to the present invention. As shown in FIG. 8, when receiving the MPDU 36, the computing unit 64 firstly checks whether MPDU_Seq# is equal to WKT_Seq#, i.e., whether the sequence number of MPDU 36 (MPDU_Seq# field 46 in FIG. 4) is equal to that of the first memory 70 (the storage value of WKT_Seq# field 72 in FIG. 6). If MPDU_Seq# is not equal to WKT_Seq#, the computing unit 64 checks whether the transmission of the MSDU 32 is normal by checking whether the MPDU_Frag# is zero. The MPDU 36 carries a new MSDU if the MPDU_Frag# is zero, and the computing unit 64 updates WKT_Seq# with the sequence numbers of the MPDU 36 and performs the integrity check process. If MPDU_Frag# is not zero, the MPDU 36 is abnormally transmitted, and the computing unit 64 shall set the third field 86 (Corrupted, C) of the descriptor 80 to be one and terminate the integrity check process of the MSDU 32.

If MPDU_Seq# is equal to WKT_Seq#, the computing unit 64 shall continue to check whether the MPDUs 36 are transmitted according to their sequence in the MSDU 32 by checking whether MPDU_Frag# is equal to WKT_Frag#+1. If MPDU_Frag# is equal to WKT_Frag#+1, the computing unit 64 shall perform the integrity check process. If MPDU_Frag# is not equal to WKT_Frag#+1, the MPDUs 36 are not transmitted according to their sequence in the MSDU 32, and the computing unit 64 shall set the storage value of the third field 86 (Corrupted, C) of the descriptor 80 to be one and terminate the integrity check process of the MSDU 32.

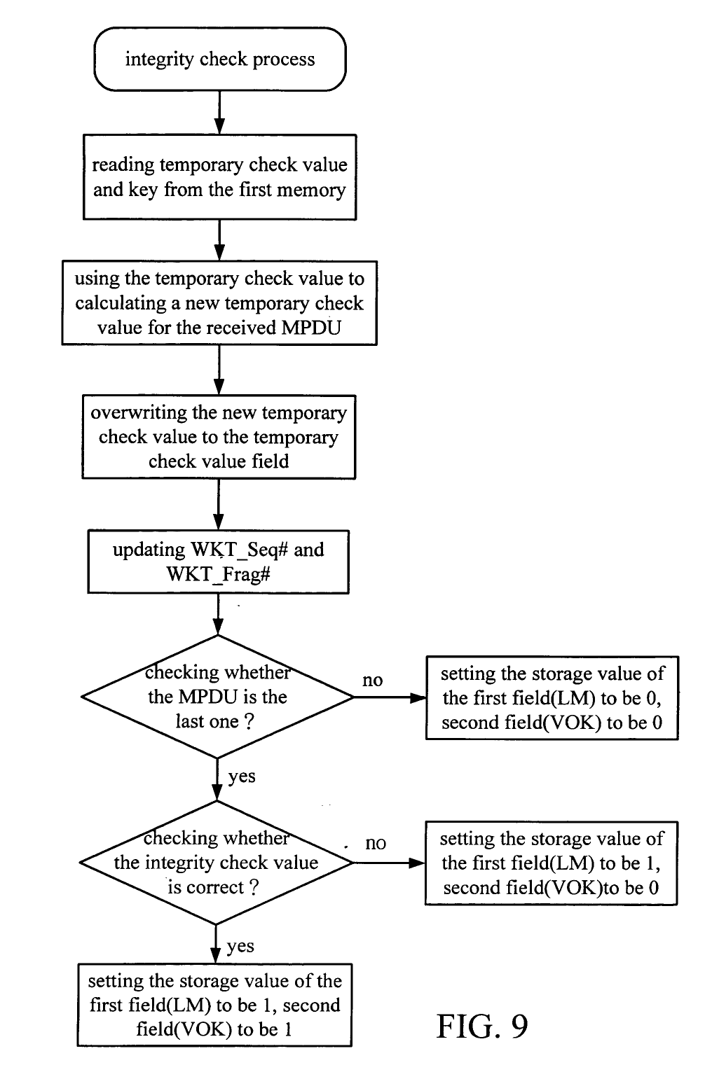

FIG. 9 is a flow chart showing the calculation process of the integrity check value according to the present invention. As shown in FIG. 9, the integrity check process reads the storage value of the key field 76 and the storage value of temporary check value field 78 (the check value of the former MPDU) from the first memory 70, and calculates the temporary check value of the received MPDU 36 with the storage value of the temporary check value field 78 as the initial value. If this MPDU 36 is the first one of the MSDU 32, the temporary check value of the received MPDU 36 is calculated with zero as the initial value.

After that, the computing unit 64 overwrites the temporary check value field 78 in the first memory 70 with the newly calculated temporary check value, WKT_Seq# of the first memory 70 with MPDU_Seq#, and WKT_Frag# with MPDU_Frag#. In addition, the computing unit 64 also appends the newly calculated temporary check value to the MPDU 36 and stores it into the data storage region 68 of the second memory 60 for reference of the CPU 54.

The computing unit 64 continues to check whether the MPDU 36 is the last one of the MSDU 32. If it is false, the storage value of the first field 82 and the second field 84 is set to be zero. If it is true, the storage value of the first field 82 is set to be one. As the last MPDU 36 of the MSDU 32, the integrity check process of the MSDU 32 is completed and the temporary check value calculated by the computing unit 64 is just the second integrity check value 98 of the MSDU 32.

After completing the calculation of the second integrity check value 98, the computing unit 64 shall check whether the second integrity check value 98 is equal to the first integrity check value 34. If it is false, the wireless network receiver 50 has not received an integrated MSDU 32, and the computing unit 64 shall set the storage value of the first field 82 to be one and that of the second field 84 to be zero for notifying the CPU 54. If it is true, the wireless network receiver 50 has received an integrated MSDU 32, and the computing unit 64 shall set the storage value of the first field 82 and the second field 84 to be one.

First of all, the CPU 54 shall check whether the storage value of the third field 86 is one. This MSDU 32 shall be discarded without reassembly if it is one, and the CPU 54 shall consider to reassemble the MSDU 32 if it is zero. The CPU 54 checks whether the storage value of the first field 82 is one to realize if all MPDU 36 of the MSDU 32 are received, and then checks the integrity of the MSDU 32 by checking if the storage value of the second field 84 is one. The CPU 54 shall reassemble MPDU 36 to MSDU 32 only when the storage value of the second field 84 is one. If the storage value of the first field 82 is one, while that of the second field is zero, the CPU 54 shall not reassemble MPDU 36 to avoid waste of time resulted from reassembling incomplete data that will reduce the overall performance of the wireless network receiver 50.

Compared with the prior art technology, the present invention can decrease the load of the CPU 54 since the computing unit 64 checks the integrity of the MSDU received by the wireless network receiver 50 without bothering the CPU 54. In addition, the CPU 54 only reassembles the MPDUs 36 into the MSDU 32 that have passed through integrity check, thus no time is wasted on reassembling incomplete data and the overall performance of the wireless network receiver 50 is enhanced.

The above-described embodiments of the present invention are intended to be illustrative only. Numerous alternative embodiments may be devised by those skilled in the art without departing from the scope of the following claims.

What is claimed is:

1. A wireless network receiver comprising:
a receiving queue for receiving protocol data units;
a computing unit electrically connected to the receiving queue for calculating an integrity check value of a service data unit from which the protocol data units are fragmented; and
a first memory for storing the integrity check value.

2. The wireless network receiver of claim 1, wherein the first memory comprises:
a transmitter address field;
a key field for storing keys for the computing unit to calculate the integrity check value; and
a temporary check value field for storing the integrity check value.

3. The wireless network receiver of claim 2, wherein the first memory further comprises a sequence number field and a fragment number field.

4. The wireless network receiver of claim 1, wherein the first memory is a static RAM.

5. The wireless network receiver of claim 1, further comprising a CPU for reassembling the protocol data units into the service data unit.

6. The wireless network receiver of claim 1, further comprising a second memory for storing the protocol data units and a memory controller for controlling the data access of the second memory.

7. The wireless network receiver of claim 6, wherein a descriptor is allocated to the protocol data units, and the descriptor comprises:
a first field for recording information indicating whether the protocol data unit being received is the last one of the service data unit;
a second field for recording the integrity check status of the service data unit; and
a third field for recording information indicating if any error occurred during the receiving procedure.

8. The wireless network receiver of claim 6, wherein the protocol data unit stored in the second memory further comprises a temporary check value field for storing a temporary check value calculated by the computing unit.

9. A method for checking the integrity of a service data unit by a wireless network receiver, the service data unit being transmitted to the wireless network receiver after a first integrity check value is calculated and fragmented into a plurality of protocol data units, the method comprising the steps of:
calculating a first temporary check value for protocol data units having been received;
storing the first temporary check value;
receiving a next protocol data unit;
calculating a second temporary check value for the next protocol data unit, wherein the second temporary check value uses the first temporary check value as an initial value;
setting the second temporary check value to be a second integrity check value for the service data unit in the wireless network receiver if all the protocol data units of the service data unit are received; and
determining the transmission of the protocol data units is correct if the first integrity check value is equal to the second integrity check value.

10. The method for checking the integrity of a service data unit by a wireless network receiver of claim 9, wherein the service data unit is a MSDU (media access control service data unit, defined in IEEE 802.11), and the protocol data unit is a MPDU (media access control protocol data unit, defined in IEEE 802.11).

11. The method for checking the integrity of a service data unit by a wireless network receiver of claim 9, further comprising a step of appending the temporary check value to the protocol data unit and storing in a second memory after the temporary check value of the protocol data unit is calculated.

12. The method for checking the integrity of a service data unit by a wireless network receiver of claim 9, further comprising the steps of:
checking whether or not a sequence number of the protocol data unit being received is correct; and
performing an abnormal transmission checking process if the sequence number is not correct.

13. The method for checking the integrity of a service data unit by a wireless network receiver of claim 12, further comprising the steps of:
checking whether or not a fragment number of the protocol data unit being received is correct if the sequence number is correct; and
terminating to check the integrity of the service data unit if the fragment number is not correct.

14. The method for checking the integrity of a service data unit by a wireless network receiver of claim 12, wherein abnormal transmission checking process comprises the steps of:
checking whether or not a fragment number of the protocol data unit being received is zero if the sequence number of the protocol data unit is not correct; and
terminating to check the integrity of the service data unit if the fragment number is not zero.

15. The method for check the integrity of a service data unit by a wireless network receiver of claim 9, further comprising a step of reassembling the plurality of the protocol data units into a service data unit if the second integrity check value is equal to the first integrity check value.
